(19) United States
(12) Patent Application Publication
(10) Pub. No.: US 2011/0226308 A1
(43) Pub. Date: Sep. 22, 2011

(54) Solar energy hybrid module

(76) Inventor: Yi Pang, Olney, MD (US)

(21) Appl. No.: 12/773,994

(22) Filed: May 5, 2010

Related U.S. Application Data
(60) Provisional application No. 61/315,057, filed on Mar. 18, 2010.

(51) Int. Cl. H01L 31/052

(52) U.S. Cl. 136/246

(57) ABSTRACT

A solar energy module assembles into an array producing electricity and heat upon exposure to light. The module includes a transparent tube; a reflector; solar cells; a pipe that is specially configured with planar walls; and an optional sun-tracking device. The reflector concentrates light to focal lines within the top part of the transparent tube. The pipe has a polygon cross-sectional shape with an odd number of flat walls, preferably three or five flat walls. A flat wall faces the top of the tube and is configured to extend across a portion of a cross-sectional shape occupied by a plurality of bottom-facing planar walls. At least two bottom-facing planar walls are each located in a focal line. A fluid in the pipe may serve as a coolant. The solar cells, preferably monocrystalline silicon photovoltaic cells, are mounted on the top flat wall and each bottom-facing planar wall to produce electricity.

### CROSS-REFERENCE TO RELATED APPLICATIONS

This application claims the benefit of U.S. Provisional Application No. 61/315,057, filed Mar. 18, 2010, which is hereby incorporated by reference herein.

### TECHNICAL FIELD

In the field of photoelectrics, a photovoltaic device for the generation of an electric and thermal energy upon exposure to light, by the direct conversion of the light to electrical energy, uses an arrangement of photoelectric cells with a concentrator, and heat extraction means.

### BACKGROUND ART

The present invention is distinguished from the prior art by a structure that seeks to simultaneously serve principles to enable the device to inexpensively convert sunlight to electricity and thermal energy by (1) obtaining a higher concentration of sunlight to reduce the amount of expensive photovoltaic cells; (2) adjusting the location of the photovoltaic surface to maximize the efficiency of the photovoltaic cell by concentrating light more or less uniformly in intensity across its surface and by enabling light to strike the surface of the photovoltaic cell as close as possible to normal to its surface; and, (3) using almost all light incident on photovoltaic cells for thermal and electric energy production, with the understanding that since thermal energy is considered as lower-grade energy source, the preference is to maximize production of electric power.

The prior art is uniform in the failure to describe a solar energy device structure that has the potential to implement the above principles. For example, use of a tube with a concentrator for a solar energy assembly is disclosed in U.S. Pat. No. 4,144,095 (the '095 patent). The '095 patent teaches a hermetically sealed tube with a trough shaped radiation reflector concentrating light on a solar cell and rotation of the assembly to follow the sun. It further teaches that a cooling fluid or inert gas may be circulated through the envelope in order to control the temperature inside the tube. The structure of the device taught in the '095 patent cannot simultaneously satisfy principles, noted above. Other more sophisticated prior art designs involve secondary optics in order to satisfy the three principles noted above.

The present invention is distinct from the '095 patent and other prior art in this field in that it includes a structure employing multiple focal lines and a solar cell configuration on the faces of a specially-shaped cooling pipe with an odd number of planar walls in meeting these three principles without secondary optics.

### SUMMARY OF INVENTION

A solar energy module that can be assembled in an array to produce electricity and extract heat upon exposure to light. The module includes a transparent tube, preferably made of glass, a reflector, solar cells, a pipe that is specially configured with planar walls and an optional sun-tracking device.

The transparent tube is preferably a right circular cylindrical body, which may hold a vacuum, or alternatively may hold a thermal insulating gas to resist heat transfer from the pipe to the wall of the transparent tube.

The reflector is positioned within the transparent tube and concentrates light to a plurality of focal lines within the top part of the transparent tube. The reflector preferably has a parabolic or compound parabolic shape. It may also include a coating on either the exterior or the interior of the bottom part of transparent tube. This configuration simplifies the structure, but it is noted that when a coating used, the transparent tube should no longer be a right circular cylinder, but rather the bottom part should be preferably comprise a parabolic or compound parabolic shape.

The pipe has a polygon cross-sectional shape with an odd number of flat walls, preferably either three or five flat walls. At least one of the flat walls faces the top of the tube and is configured to extend across a portion of a cross-sectional shape occupied by a plurality of bottom-facing planar walls. At least two bottom-facing planar walls are each located in a focal line. Solar cells, preferably monocrystalline silicon photovoltaic cells, are mounted the top flat wall and each bottom-facing planar wall. The angles of bottom-facing planar walls are preferably adjusted to be normal to the incident light. The pipe may contain a low evaporating point fluid to serve as a coolant that absorbs heat by phase transition.

### TECHNICAL PROBLEM

Existing solar photovoltaic, concentrating photovoltaic, or concentrating photovoltaic and thermal combination devices suffer from inefficiency, high cost, or insufficient modularity to enable application versatility.

The efficiency of a photovoltaic cell in producing power is dependent on the amount of sunlight impinging on the cell and its steady state temperature. The efficiency generally decreases at higher operating temperatures. Thus, there is room for improvement over the prior art when more sunlight can be concentrated on the solar cell while at the same time without increasing its operating temperature significantly and extracting the thermal energy for hot water or space heating.

Most solar concentrator technology on the market typically results in higher cost and is generally not amenable to production in modular systems. The large-scale construction usually required for solar concentrators, the consequent large scale, sturdy sun-tracking mechanisms required to point the solar system towards the sun, and the significant size of cooling systems have made concentrator photovoltaic systems uneconomical for most applications.

To maximize current state of the art solar cell efficiency, the optical system should be constrained so that light impinges on the solar cell uniformly, as close to normal to the cell surface as possible and across the full cell surface area. Currently most of the concentrator photovoltaic and concentrator photovoltaic thermal devices do not adhere to these constraints, and consequently suffer from lower optical efficiency.

### SOLUTION TO PROBLEM

The solution to the problem is a unique hybrid system that maximizes electricity and heat production from incident solar radiation by using a transparent tube containing a concentrator and solar cells mounted to a structured, flat-walled pipe, which efficiently extracts heat using a coolant within the pipe.

### ADVANTAGEOUS EFFECTS OF INVENTION

The present invention offers a highly efficient module that can be assembled into an array for almost any application in order to maximally produce electricity from incident solar radiation using solar cells mounted on multiple flat surfaces within a transparent tube, and also producing useful heat energy by efficiently extracting heat otherwise wasted or contributing to system inefficiencies. Its unique structure enables the optimal optical efficiency in which light is concentrated on the photovoltaic cell uniformly and close to normal to the photovoltaic cell.

### BRIEF DESCRIPTION OF DRAWINGS

The drawings illustrate preferred embodiments of the solar energy hybrid module according to the invention and the reference numbers in the drawings are used consistently throughout. New reference numbers in FIG. 2 are given the 200 series numbers. Similarly, new reference numbers in each succeeding drawing are given a corresponding series number beginning with the figure number.

FIG. 1 is an end view of an embodiment of the module.

FIG. 2 is an end view of a second embodiment of the module.

FIG. 3 is an elevation view of the pipe.

FIG. 4 is a perspective view of a third embodiment of the module.

### DESCRIPTION OF EMBODIMENTS

In the following description, reference is made to the accompanying drawings, which form a part hereof and which illustrate several embodiments of the present invention. The drawings and the preferred embodiments of the invention are presented with the understanding that the present invention is susceptible of embodiments in many different forms and, therefore, other embodiments may be utilized and structural, and operational changes may be made, without departing from the scope of the present invention.

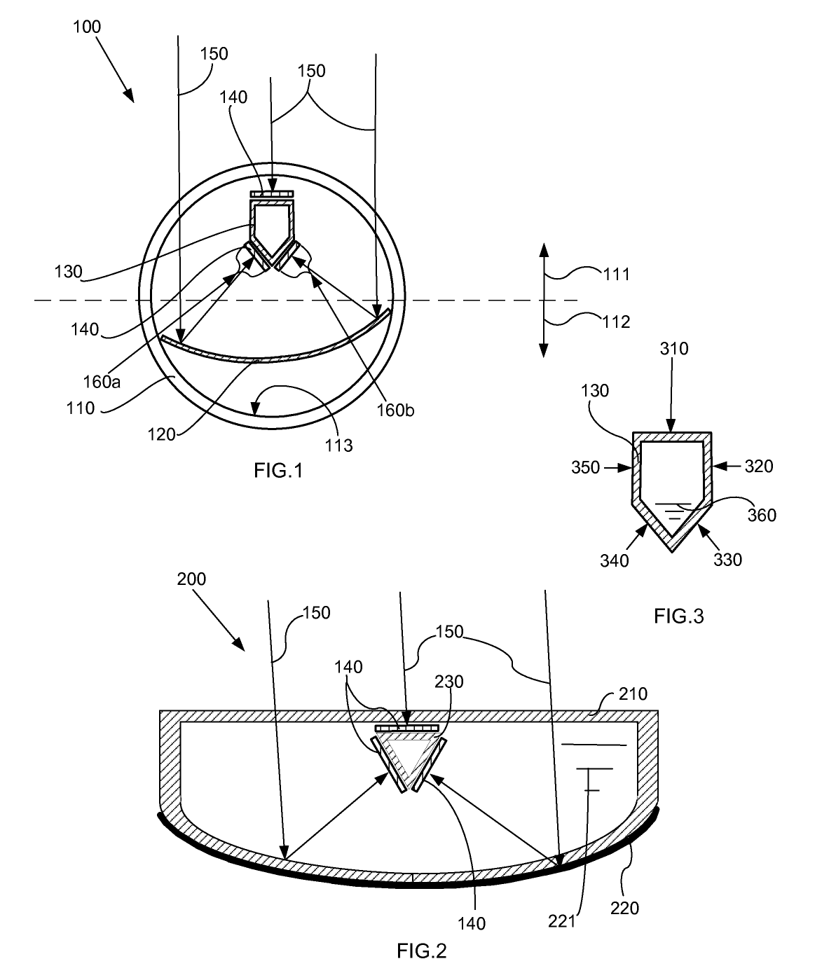

FIG. 1 illustrates a preferred embodiment of the solar energy hybrid module for extracting electricity and heat upon exposure to light. FIG. 4 shows a perspective view of a similar embodiment. The module (100) includes a transparent tube (110), a reflector (120), a pipe (130), photovoltaic cells (140), a coolant (360) within the pipe, and optionally a sun-tracking device (430).

The transparent tube (110) is preferably an elongated right-circular cylindrical container having a length (440); a top part (111) and a bottom part (112). Any shaped transparent tube, however, is within the scope of the invention. Thus, the term “tube” as used herein includes any conduit consisting of a long hollow object. The top part (111) and a bottom part (112) terminology are for reference and best understood in terms of when the module is in a horizontal position with the understanding that the module (100) may be installed at any inclination, especially in consideration that the best installation for maximal efficiency will be obtained when solar radiation shines perpendicularly to the axis of the transparent tube (110). The transparent tube (110) is preferably glass, which is a durable material in the presence of solar radiation. Plastic is also an acceptable transparent material and current technology for plastics is making them more durable in sunlight, particularly ultraviolet light.

The transparent tube (110) is preferably configured to hold a vacuum to minimize heat loss by convection from the pipe (130) to the wall (113) of the transparent tube (110). Alternatively, the transparent tube (110) may hold a thermal insulating gas (221) within the transparent tube (110). The thermal insulating gas (221) is one having properties that reduce heat transfer from the pipe (130) to the wall (113) of the transparent tube. A typical insulating gas (22) is argon.

The reflector (120) is configured to concentrate light to a plurality of focal lines within the top part of the transparent tube (110) after the light enters into the transparent tube through the top part (111). For example a left focal line (160a) and a right focal line (160b).

Each focal line may be a wide line, that is, one occupying a large cross-sectional area, but is preferably of a linear shape running parallel to the axis of the transparent tube (110). The reflector (120) is preferably configured to spread the focal line across the width of the photovoltaic cells (140) to evenly concentrate the light (150) over the surface of the solar cells to maximize power generation. Thus, the reflector (120) is preferably a concentrating mirror positioned within the bottom part (112) of the transparent tube (110).

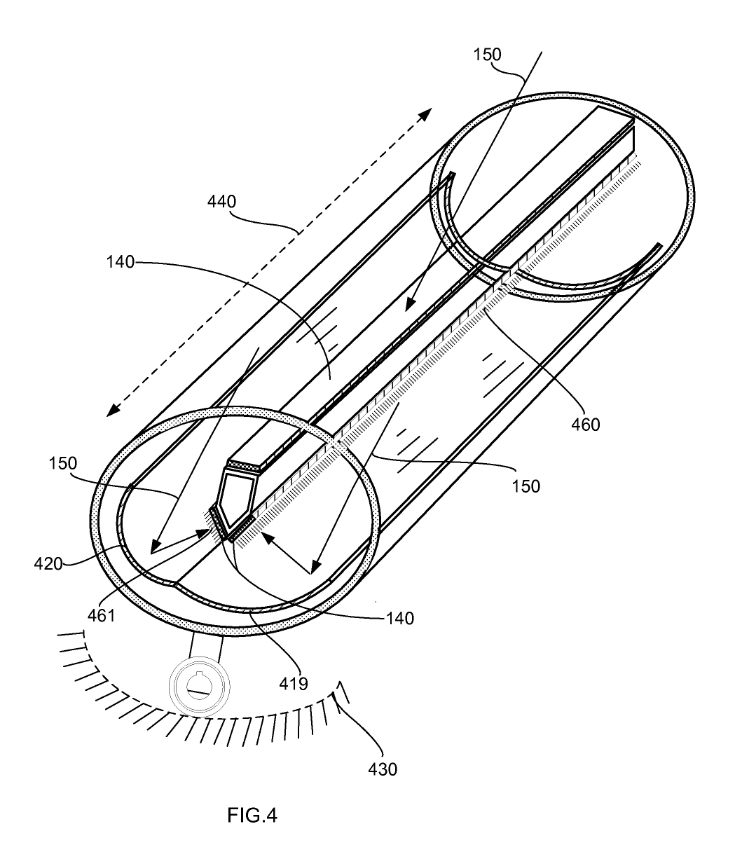

FIG. 4 shows reflector with a first portion (419) and a second portion (420). The first portion (419) reflects to a focal line (460), indicated by the closely-spaced parallel lines extending over the photovoltaic cells (140) on the planar face of the pipe (130), shown in FIG. 3 as the first bottom-facing planar wall (330). The second portion (420) reflects to a focal line (461), indicated by the closely-spaced parallel lines extending over the photovoltaic cells (140) on the planar face of the pipe (130), shown in FIG. 3 as the second bottom-facing planar wall (340). In either case, the first portion (419) and the second portion (420) preferably extend the full length (440) of the transparent tube (110) in order to maximize the amount of light (150) concentrated in each focal line. Preferably, the reflector (120) is configured with either a parabolic shape or a compound parabolic shape and is optimized to evenly concentrate the light (150) over the surface of the solar cells to maximize power generation.

FIG. 2 shows an alternative embodiment, or second module (200) employing a reflector (220) comprising a coating, also known as a mirror finish, on the exterior of the bottom part of the transparent tube (110). The light (150) passes through the wall (113) of the transparent tube (110), strikes the mirror finish of the coating and is reflected back to one or more focal lines. Such coating may also be on the interior of the bottom part of the transparent tube (110).

The pipe (130) is configured to define a cross-sectional shape formed by an odd number of planar walls. FIG. 3 illustrates 5 planar walls: a top-facing planar wall (310); a right-facing planar wall (320); a first bottom-facing planar wall (330); a second bottom-facing planar wall (340); and a left-facing planar wall (350). FIG. 2 illustrates an irregular cross-section transparent tube (210) and a pipe (230) with three planar walls. The planar walls are also referred to as faces of the pipe.

The pipe (130) is further configured such that the top-facing planar (310) wall extends across a portion of a cross-sectional shape occupied by a plurality of bottom-facing planar walls, which in this case is the first bottom-facing planar wall (330) and the second bottom-facing planar wall (340). The top-facing planar (310) wall preferably receives light (150) directly after it enters into the transparent tube (100) through the top part (111).

The pipe (130) is further configured such that at least two bottom-facing planar walls are each located in one of the plurality of focal lines. This is illustrated in the embodiment shown in FIG. 3. These two bottom-facing planar walls are the first bottom-facing planar wall (330) and the second bottom-facing planar wall (340). The bottom facing planar walls are preferably configured to receive the concentrated light uniformly across the surface and as close to normal to the cell surface as possible. Mathematical calculation or computer-aided ray-tracing analysis has been found helpful in perfecting this configuration.

The pipe (130) is preferably configured to conduct heat out of the transparent tube (110). This may be aided when the pipe (130) is made of heat conducting material, which is preferably a metal such as copper or aluminum. In order to transfer heat, there is preferably a heat sink outside the transparent tube (110) connected to the pipe (130) to remove heat therefrom.

The photovoltaic cells (140) are attached to the pipe (130) in a configuration that enables heat to be conducted away from the photovoltaic cells (140) by the pipe (130). Preferably, this is a direct contact conduction path from the solar cells to the pipe (130) planar walls.

The photovoltaic cells (140) are preferably configured from monocrystalline silicon, and are attached along the top-facing planar wall (310) and along each bottom-facing planar wall. The bottom-facing planar walls for the embodiment shown in FIG. 3 are the first bottom-facing planar wall (330) and the second bottom-facing planar wall (340). Other embodiments may have more than one top-facing planar wall and more than two bottom-facing planar walls.

Each focal line of the reflector reflects light to at least one planar wall and the plurality of photovoltaic cells are further attached along each such planar wall near each focal-line.

The optional coolant (360) preferably consist of a low evaporating point fluid, also known as a low boiling point fluid, that absorbs heat by phase transition is configured to flow through the pipe and out of the transparent tube (110). This enables the pipe (130) to operate similarly to the physics of a heat pipe. The coolant (360) may be a simple liquid that flows into the transparent tube (110), absorb heat from the pipe (130) and then flows out the transparent tube (110) into a heat exchanger. The coolant (360) reduces the photovoltaic cell temperature while extracting the thermal energy for useful purposes. For example, the coolant (360) can be heat-exchanged to produce hot water or provide space heating. This will lower the coolant (360) temperature for reuse in the transparent tube (110). Alternatively, the coolant can be made to phase reverse transition (from a gas to a liquid) to release heat and consequently cool itself. Such coolants are commonly used as refrigerants. Examples of low boiling point fluids are methyl alcohol, aqueous ammonia or a calcium chloride ammonia mixture.

An optional sun-tracking device (430) is configured to rotate the transparent tube (110) so that the top part (111) receives a maximal amount of light (150) from the sun. Such sun-tracking devices are well known in the art.

The above-described embodiments including the drawings are examples of the invention and merely provide illustrations of the invention. Other embodiments will be obvious to those skilled in the art. Thus, the scope of the invention is determined by the appended claims and their legal equivalents rather than by the examples given.

### INDUSTRIAL APPLICABILITY

The invention has application to the electric energy industry and the heating industry.

What is claimed is:

1. A module for extracting electricity and heat upon exposure to light, the module comprising:
a transparent tube comprising a top part and a bottom part;
a reflector configured to concentrate light to a plurality of focal lines within the top part of the transparent tube after the light enters into the transparent tube through the top part;
a pipe configured:
to define a cross-sectional shape formed by an odd number of planar walls, the planar walls comprising;
a top-facing planar wall configured to extend across a portion of a cross-sectional shape occupied by a plurality of bottom-facing planar walls;
at least two bottom-facing planar walls, each such bottom-facing planar wall located in one of the plurality of focal lines; and,
a plurality of photovoltaic cells attached to the pipe in a configuration:
that enables heat to be conducted away from the photovoltaic cells by the pipe;
along the top-facing planar wall; and,
along each bottom-facing planar wall.

2. The module of claim 1, wherein the reflector comprises a reflective coating on a surface of the bottom part of the transparent tube.

3. The module of claim 1, wherein the transparent tube is configured to hold a vacuum to minimize heat loss by convection from the pipe to the wall of the transparent tube.

4. The module of claim 1, further comprising a thermal insulating gas within the transparent tube comprising properties that reduce heat transfer from the pipe to the wall of the transparent tube.

5. The module of claim 1, wherein the pipe comprises a coolant, the coolant consisting of a low evaporating point fluid that absorbs heat by phase transition.

6. The module of claim 1, wherein the pipe comprises five planar walls.

7. The module of claim 1, wherein the pipe comprises three planar walls.

8. The module of claim 1, wherein the transparent tube is a right circular cylindrical body.

9. The module of claim 1, wherein the reflector comprises a shape selected from the group consisting of parabolic and compound parabolic.

10. The module of claim 1, wherein the photovoltaic cells are configured from monocrystalline silicon.
